(19) United States
(12) Patent Application Publication
(10) Pub. No.: US 2012/0002379 A1
(43) Pub. Date: Jan. 5, 2012

(54) CIRCUIT BOARD STRUCTURE

(75) Inventor: MING-CHUN HSIUNG, Shindian (TW)

(73) Assignee: FIH (HONG KONG) LIMITED, Kowloon (HK)

(21) Appl. No.: 12/856,733

(22) Filed: Aug. 16, 2010

(30) Foreign Application Priority Data
Jun. 30, 2010 (CN) 201020242823.2

(51) Int. Cl. H05K 1/14

(52) U.S. Cl. 361/749

(57) ABSTRACT

A circuit board structure includes a rigid circuit board, a flexible circuit board connected to the rigid circuit board and a fixing member positioned between the rigid circuit board and the flexible circuit board. The flexible circuit board is folded over the rigid circuit board. The fixing member is secured to the rigid circuit board latching the flexible circuit board.

### BACKGROUND

1. Technical Field

The present disclosure relates to circuit board structures, particularly to a circuit board being a combination of a rigid circuit board and a flexible circuit board.

2. Description of Related Art

Portable electronic devices include circuit boards integrated with electrical components mounted inside for different functions. The circuit boards usually are a combination of rigid circuit boards and flexible circuit boards. The electrical members such as a USB interface or an earphone jack are positioned on the circuit board to receive other accessories such as an earphone. In use, the flexible circuit board portion of the circuit board may be moved for removing the accessories from the portable electronic device.

Therefore, there is room for improvement within the art.

### BRIEF DESCRIPTION OF THE DRAWINGS

Many aspects of the circuit board structure can be better understood with reference to the following drawings. The components in the drawings are not necessarily drawn to scale, the emphasis instead being placed upon clearly illustrating the principles of the circuit board structure.

FIG. 1 is a schematic view of a circuit board structure, according to an exemplary embodiment.

FIG. 2 is an exploded view of the circuit board structure shown in FIG. 1.

FIG. 3 is a schematic view of a fixing member shown in FIG. 1.

FIG. 4 is a partially assembled view of the circuit board structure shown in FIG. 1.

### DETAILED DESCRIPTION

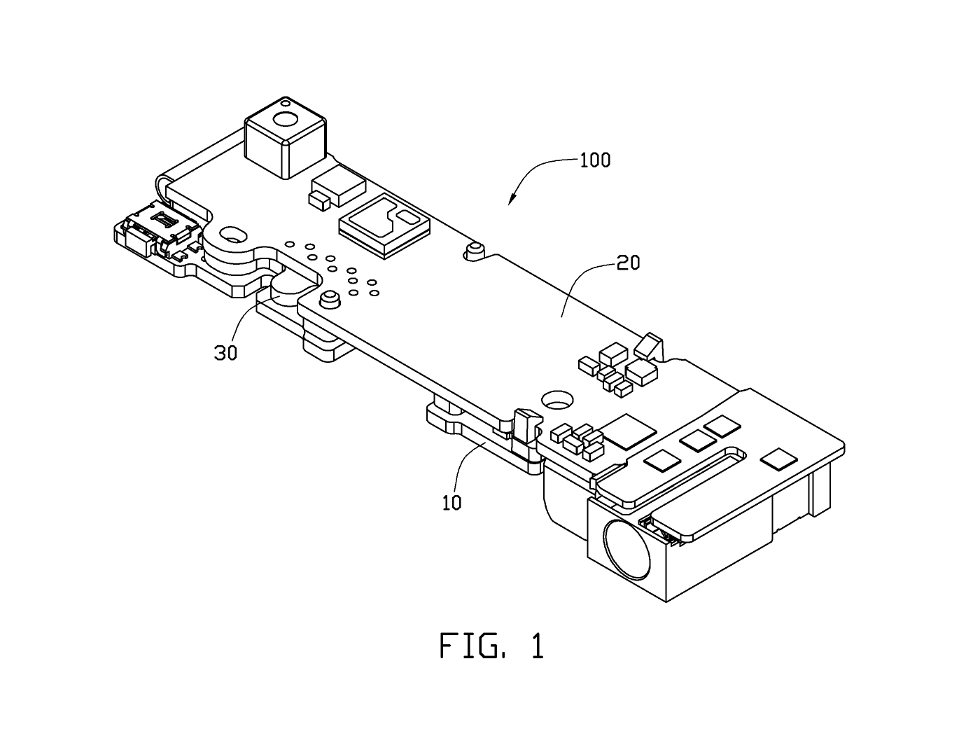

FIG. 1 shows a circuit board structure 100 used in a portable electronic device. In this exemplary embodiment, the electronic device is a mobile phone. The circuit board structure 100 includes a rigid circuit board 10, a flexible circuit board 20 connected to the rigid circuit board 10, a fixing member 30 and a washer 40. The fixing member 30 is positioned between the rigid circuit board 10 and the flexible circuit board 20 when the fixing member 30 is secured to the rigid circuit board 10 and latches to the flexible circuit board 10 (FIG. 1).

The rigid circuit board 10 is substantially a rectangular flat board having a plurality of electrical members (not labeled). The rigid circuit board 10 defines a positioning hole 11 therein.

The flexible circuit board 20 is connected to the rigid circuit board 10. An electrical member 21 is mounted on one end of the flexible circuit board 20 opposite to the rigid circuit board 10. The electrical member 21 may be an earphone jack. The flexible circuit board 20 defines two opposite cutouts 22 at its edges and substantially adjacent to the electrical member 21, a positioning slot 23 at a middle portion of one edge, and a positioning hole 24 diagonally opposite to the positioning slot 23 at a near end.

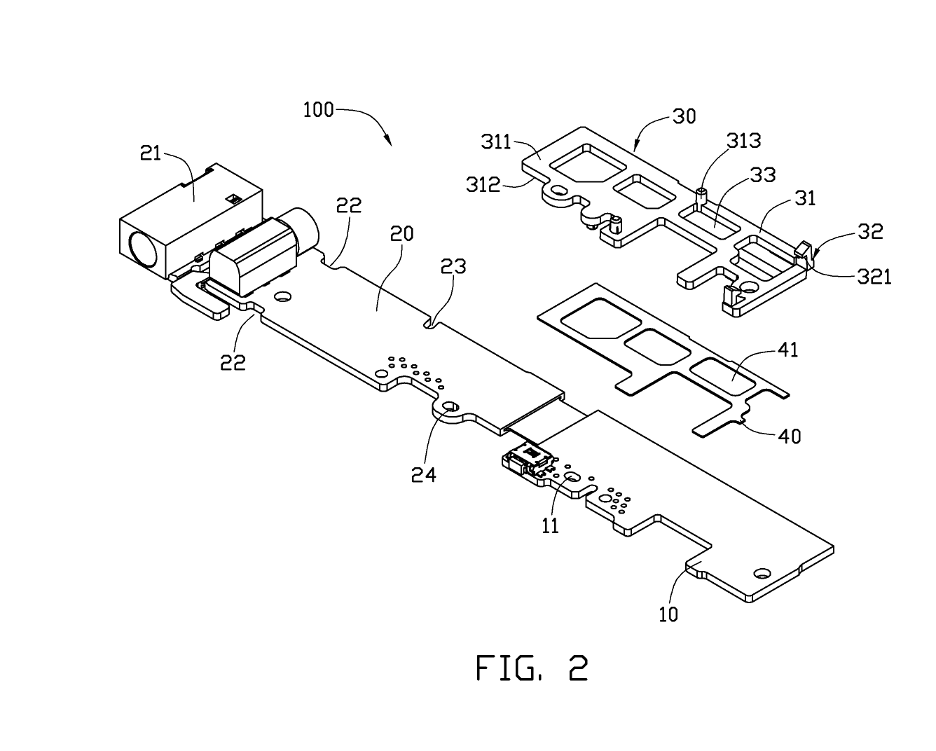

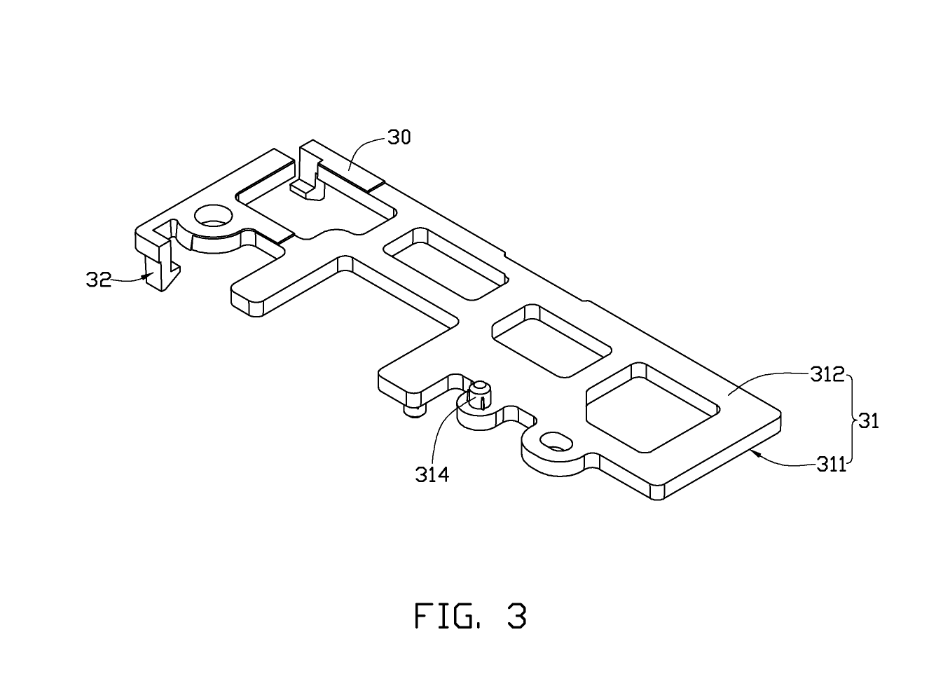

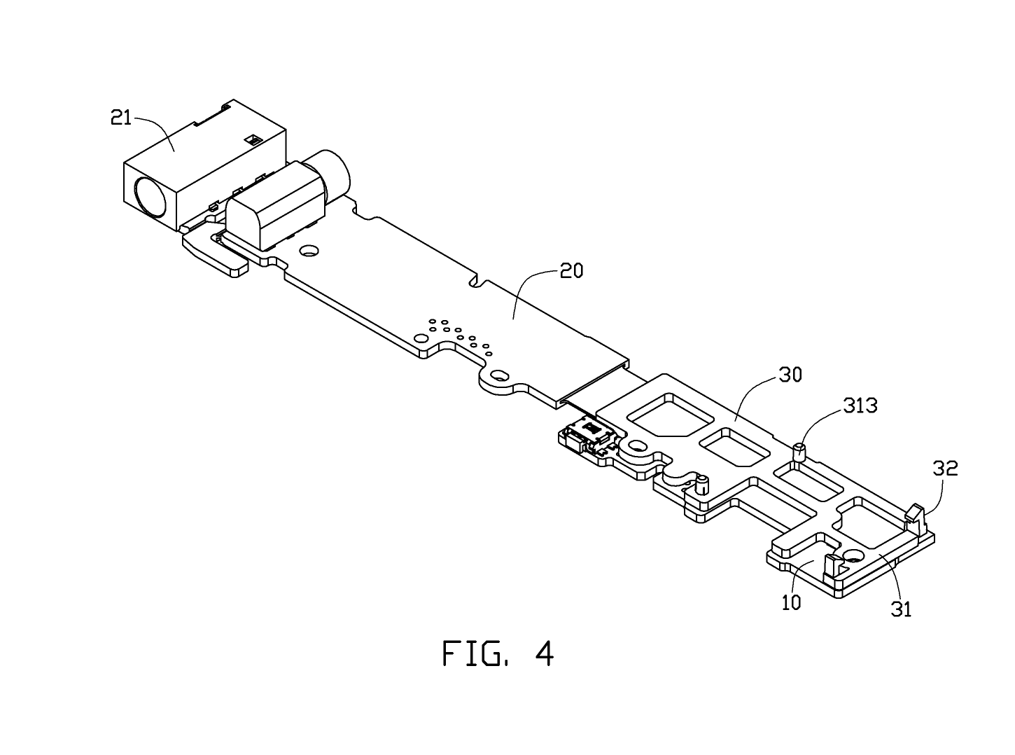

Also referring to FIG. 3, the fixing member 30 includes a main body 31 and a latching portion 32. The main body 31 includes a first surface 311 and an opposite second surface. Two positioning posts 313 (FIG. 4) protrude from the first surface 311 and correspond in positions to the positioning slot 23 and the positioning hole 24. A positioning post 314 protrudes from the second surface 312 corresponding to the positioning hole 11. The latching portion 32 includes two opposing hooks 321 (FIG. 2) positioned at opposite edges of an end of the same side of the first surface 311.

The washer 40 is an elastic sheet positioned between the main body 31 and the rigid circuit board 10 to protect the rigid circuit board 10. The washer 40 and the fixing member 30 define a number of corresponding through holes 41 and 33, to receive other electrical components (not shown) mounted on the rigid circuit board 10.

Referring to FIG. 4, to assemble the circuit board structure 100, the main body 31 of the fixing member 30 is secured on the rigid circuit board 10. The positioning post 314 extends through the positioning hole 11 of the rigid circuit board 10. The washer 40 is sandwiched between the main body 31 and the rigid circuit board 10. The flexible circuit board 20 is then folded over the first surface 311 of the fixing member 30. The positioning posts 313 respectively extend through the positioning slot 23 and the positioning hole 24. The hooks 321 latch the flexible circuit board 20 toward the rigid circuit board 10.

The flexible circuit board 20 latched by the hooks 321 is stable and cannot be easily moved by operation of the electrical member 21.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A circuit board structure, comprising:
a rigid circuit board;
a flexible circuit board connected to the rigid circuit board and folded over the rigid circuit board; and
a fixing member positioned between the rigid circuit board and the folded over flexible circuit board, secured to the rigid circuit board and latching to the flexible circuit board.

2. The circuit board structure as claimed in claim 1, wherein the fixing member includes a main body and a latching portion positioned at one end of the main body, the main body is secured to the rigid circuit board, the latching portion latches to the flexible circuit board.

3. The circuit board structure as claimed in claim 2, wherein the latching portion includes two spaced-apart opposing hooks, the two hooks latching the flexible circuit board.

4. The circuit board structure as claimed in claim 3, wherein the main body includes a first surface and a opposite second surface, the first surface is secured to the rigid circuit board, the second surface includes a plurality of positioning posts and the latching portion, the positioning posts extend through the flexible circuit board.

5. The circuit board structure as claimed in claim 4, wherein the flexible circuit board defines a plurality of positioning holes, each positioning post extending through positioning hole.

6. The circuit board structure as claimed in claim 1, wherein the flexible circuit board includes an earphone jack positioned at one side thereof.

7. The circuit board structure as claimed in claim 1, further comprising a washer sandwiched between the rigid circuit board and the fixing member.

8. The circuit board structure as claimed in claim 7, wherein the washer and the rigid circuit board define a plurality of though holes to receive other electrical member positioned on the rigid circuit board.

9. A circuit board structure, comprising:
a rigid circuit board;
a flexible circuit board mounted to the rigid circuit board;
an electrical member mounted on one end of the flexible circuit board opposite to the rigid circuit board; and
a fixing member positioned between the rigid circuit board and the flexible circuit board, and latching the flexible circuit board.

10. The circuit board structure as claimed in claim 9, wherein the electrical member is an earphone jack.

11. The circuit board structure as claimed in claim 9, wherein the fixing member includes a main body and a latching portion positioned at one end of the main body, the main body is secured to the rigid circuit board, the latching portion latches the flexible circuit board.
